(19) United States
(12) Patent Application Publication
(10) Pub. No.: US 2022/0162739 A1
(43) Pub. Date: May 26, 2022

(54) IMPROVED COATING PROCESSES

(71) Applicant: Nanofilm Technologies International Limited, Singapore (SG)

(72) Inventors: Xu SHI, Singapore (SG); Zhi TANG, Singapore (SG); Zhang Yang RONG, Singapore (SG)

(73) Assignee: Nanofilm Technologies International Limited, Singapore (SG)

(21) Appl. No.: 17/437,648

(22) PCT Filed: Mar. 13, 2020
(86) PCT No.: PCT/EP2020/056864

§ 371 Date: Sep. 9, 2021

(30) Foreign Application Priority Data
Mar. 15, 2019 (EP) 19163306.4

(51) Int. Cl. C23C 14/06; C23C 14/32; C23C 14/35; C23C 14/16; C23C 14/02

(52) U.S. Cl. CPC C23C 14/0605; C23C 14/325; C23C 14/025; C23C 14/165; C23C 14/35

(57) ABSTRACT

A method of depositing a coating on a substrate comprises simultaneously depositing a first material via a CVA process and a second material via a sputtering process; also described are coatings obtained therefrom and coated substrates.

### INTRODUCTION

This present invention relates to coatings with improved properties produced by a combination of sputtering and other processes and methods for producing such coatings.

### BACKGROUND TO THE INVENTION

A large variety of deposition techniques are used to coat substrates. Vapor deposition technology is typically used to form thin film deposition layers in various types of applications, including microelectronic applications and heavy-duty applications. Such deposition technology can be classified in two main categories. A first category of such deposition technology is known as Chemical Vapor Deposition (CVD). CVD generally refers to deposition processes occurring due to a chemical reaction. Common examples of CVD processes include semiconducting Si layer deposition, epitaxy and thermal oxidation.

A second category of deposition is commonly known as Physical Vapor Deposition (PVD). PVD generally refers to the deposition of solid substances occurring as a result of a physical process. The main concept underlying the PVD processes is that the deposited material is physically transferred onto the substrate surface via direct mass transfer. Typically, no chemical reaction takes place during the process and the thickness of the deposited layer is independent of chemical reaction kinetics as opposed to CVD processes.

Sputtering is a known physical vapor deposition technique for depositing compounds on a substrate, wherein atoms, ions or molecules are ejected from a target material (also called the sputter target) by particle bombardment so that the ejected atoms or molecules accumulate on a substrate surface as a thin film.

Another known physical vapor deposition technique is cathodic vapor arc (CVA) deposition methods. In this method, an electric arc is used to vaporize material from a cathode target. Consequently, the resulting vaporized material condenses on a substrate to form a thin film of coating. Filtered cathodic vacuum arc (FCVA) processes in particular produce clean, dense coatings.

Amorphous carbon is a free, reactive form of carbon which does not have a crystalline form. Various forms of amorphous carbon films exist and these are usually categorised by the hydrogen content of the film and the sp²:sp³ ratio of the carbon atoms in the film.

In an example of the literature in this field, amorphous carbon films are categorised into 7 categories (see table below taken from “Name Index of Carbon Coatings” from Fraunhofer Institut Schich- and Oberflächentechnik):

Amorphous Carbon Films

| Hydrogen-Free | | | Hydrogenated | | | |
|---|---|---|---|---|---|---|
| | | Modified | | | Modified with | |
| Unmodified | | With metals | Unmodified | | Metals | Non-metals |
| sp² | sp³ | sp² | sp² or sp³ | sp³ | sp² | sp² |
| Hydrogen- | Tetrahedral, | Metal- | Hydrogenated | Tetrahedral, | Metal- | Non-metal |
| free | hydrogen- | containing, | amorphous | hydrogenated | containing, | containing |
| amorphous | free | hydrogen- | carbon | amorphous | hydrogenated | hydrogenated |
| carbon | amorphous | free | | carbon | amorphous | amorphous |
| | carbon | amorphous | | | carbon | carbon |
| | | carbon | | | | |
| a-C | ta-C | a-C:Me | a-C:H | ta-C:H | a-C:H:Me | a-C:H:X |

Tetrahedral hydrogen-free amorphous carbon (ta-C) is characterised in that it contains little or no hydrogen (less than 5% mol, typically less than 2% mol) and a high content of sp³ hybridised carbon atoms (typically greater than 80% of the carbon atoms being in the sp³ state).

Whilst the term “diamond-like carbon” (DLC) is sometimes used to refer to all forms of amorphous carbon materials, the term as used herein refers to amorphous carbon materials other than to-C. Common methods of DLC manufacture use hydrocarbons (such as acetylene), hence introducing hydrogen into the films (in contrast to ta-C films in which the raw material is typically hydrogen free high purity graphite).

In other words, DLC typically has an sp² carbon content of greater than 50% and/or a hydrogen content of 20% mol and above. The DLC may be undoped or doped with metals or non-metals (see table above).

A wide range of materials can be deposited by sputtering and hence sputtering provides a method of producing a large variety of coatings. However, coatings produced by sputtering tend to be less hard and less wear resistant than coatings produced by other methods, such as FCVA. This unfortunately limits their application.

Whilst ta-C coatings produced via FCVA are significantly harder than sputtered coatings, the final appearance of the coatings are a monotonous grey colour and therefore the coatings are not desirable for certain applications where the coating aesthetics are also important.

US 2002/007796 A1 (Gorokhovsky), WO 02/070776 A1 (Commw Scient and Ind Res 0), EP 0306612 A1 (Balzers Gochvakuum), EP 0668369 A1 (Hauzer Holding) and CN 108823544 A (Yang Jieping) all describe coating apparatus comprising an arc source and a sputter target. However, these documents do not describe coating a substrate with ta-C. US 2017/121810 A1 (Avelar Araujo Juliano et al) describes substrates coated with a metal and a diamond-like layer. However, this document does not describe coating a substrate with ta-C using an FCVA apparatus.

There therefore exists the need for sputter-based coatings with a wider range of applications, but which also have greater hardness and wear resistance compared to conventional sputtered coatings, as well as a need for methods and apparatus to deposit such coatings.

### THE INVENTION

The inventor of the present application has developed a coating method which provides a modification of sputtering-based processes. In one use, the invention can produce a coating with a layer deposited by sputtering, but with increased density and/or hardness compared to conventional sputtered coatings.

It has been hitherto found that applying a sputtered material directly onto a layer deposited via FCVA (or vice versa) can result in poor adhesion between the two layers and therefore make the resulting coating susceptible to fracture or breakage. A co-deposition coating method described herein to form an intermediate “adhesion-promoting” layer overcomes this problem. Thus, in another use, the invention can provide a sputter coating with improved adhesion to another coating, e.g. one deposited by a FCVA method.

The present invention accordingly provides a method of depositing a coating on a substrate, the method comprising simultaneously depositing a first material via a CVA process and a second material via a sputtering process.

As FCVA coating processes normally occur at pressures in the milli-Pascal range, whereas sputtering usually requires inert gas pressures of greater than 0.1 Pa, it was not previously envisaged that the two coating processes (i.e. CVA and sputtering) could be used simultaneously. However, the inventor of the present invention has surprisingly found that the strong plasma flux generated during CVA coating can reduce the pressure required for sputtering. Accordingly, when performed alongside a CVA coating method, the pressure at which sputtering can be carried out can be much lower than previously expected. Examples discussed in more detail below illustrate the co-deposition method being used.

The co-deposited layer producible according to the invention can be used as an intermediate layer between a layer of a material deposited via a CVA process and a layer of another material deposited via a sputtering process. This intermediate layer promotes adhesion of the two layers (compared to if the layer deposited by CVA was applied directed to the layer deposited by sputtering, or vice versa).

Accordingly, the invention also provides a method of depositing a coating comprising a first material and a second material on a substrate, the method comprising:
i) depositing the first material via a CVA process to form a lower layer;
ii) simultaneously depositing the first material via the CVA process and the second material via a sputtering process to form a transition layer; and
iii) depositing the second material via a sputtering process to form an upper layer.

Alternatively, the invention also provides a method of depositing a coating comprising a first material and a second material on a substrate, the method comprising:
i) depositing the second material via a sputtering process to form a lower layer;
ii) simultaneously depositing the first material via a CVA process and the second material via a sputtering process to form a transition layer; and
iii) depositing the first material via the CVA process to form an upper layer.

In this context a transition layer is located intermediate between a CVA-deposited layer and a sputter-deposited layer, whichever order in which they were deposited.

The invention also provides a substrate coated with a multi-layer coating using a method as described herein.

The invention also provides a substrate coated with a coating comprising:
i) a layer deposited via a sputtering process;
ii) a transition layer between (i) and (iii) deposited by a process comprising simultaneous CVA deposition and a sputtering process; and
iii) a layer deposited by CVA deposition.

The invention further provides a coating apparatus comprising:
i) a substrate station, for location of a substrate to be coated;
ii) a CVA station, for depositing material via CVA onto the substrate;
iii) a sputtering station, for depositing material via a sputtering process onto the substrate; and
iv) a control unit that is capable of operating the CVA and sputtering stations simultaneously.

Thus, the invention enables coating of a substrate with a material that can be deposited by sputtering, but with increased hardness and wear resistance and without substantially compromising the structural integrity of the coating.

### DETAILED DESCRIPTION OF THE INVENTION

As discussed above, the term “tetrahedral amorphous carbon” (ta-C) as used herein refers to amorphous carbon having a low hydrogen content and a low sp² carbon content.

Ta-C is a dense amorphous material described as composed of disordered sp³, interlinked by strong bonds, similar to those that exist in disordered diamond (see Neuville S, “New application perspective for tetrahedral amorphous carbon coatings”, QScience Connect 2014:8, http://dx.doi.org/10.5339/connect.2014.8). Due to its structural similarity with diamond, ta-C also is a very hard material with hardness values often greater than 30 GPa.

For example, the ta-C may have a hydrogen content less than 10%, typically 5% or less, preferably 2% or less (for example 1% or less). The percentage content of hydrogen provided here refers to the molar percentage (rather than the percentage of hydrogen by mass). The ta-C may have an sp² carbon content less than 30%, typically 20% or less, preferably 15% or less. Preferably, the ta-C may have a hydrogen content of 2% or less and an sp² carbon content of 15% or less. The ta-C is preferably not doped with other materials (either metals or non-metals).

By contrast, the term “diamond-like carbon” (DLC) as used herein refers to amorphous carbon other than to-C. Accordingly, DLC has a greater hydrogen content and a greater sp² carbon content than to-C. For example, the DLC may have a hydrogen content of 20% or greater, typically 25% or greater, for example 30% or greater. The percentage content of hydrogen provided here again refers to the molar percentage (rather than the percentage of hydrogen by mass). The DLC may have an sp² carbon content of 50% or greater, typically 60% or greater. Typically, the DLC may have a hydrogen content of greater than 20% and an sp² carbon content of greater than 50%. The DLC may be undoped or doped with metals and/or non-metals.

The invention advantageously provides coatings formed from sputtered materials with hardness and wear resistance.

The present invention provides a method (“Method A”) of depositing a coating on a substrate, the method comprising simultaneously depositing a first material via a CVA process and a second material via a sputtering process. FCVA is a preferred CVA process.

Magnetron sputtering usually occurs under an Argon atmosphere at a pressure of about 2 mTorr to 10 mTorr (0.27 Pa to 1.33 Pa). However, the normal working pressure for an FCVA coating process is typically less than 2.0E-5 Torr (2.7mPa) and an additional assisting gas (such as Ar) is not required. In a FCVA process, the plasma is sustained by an arcing process.

The inventor of the present invention has found that despite the different (and previously believed to be mutually exclusive) conditions that are usually used for sputtering and CVA coating processes, it is possible to coat substrates with these two processes simultaneously.

The simultaneous co-deposition process may occur at pressures between 0.3 mTorr and 1.5 mTorr (0.040 Pa and 0.20 Pa), for example between 0.5 mTorr and 1.0 mTorr (0.067 Pa and 0.13Pa). Whilst under such a low-pressure magnetron sputtering is not usually effective by itself, using plasma generated by an FCVA process, a glow discharge can start on a magnetron sputtering cathode surface and sputtering can function normally.

Hence, in the presence of CVA plasma, sputtering processes can operate at lower chamber pressures than previously believed possible. In this way, FCVA deposition and sputtering deposition can work together to deposit a layer formed from both the FCVA and the sputtering materials. The co-deposited layer solves the adhesion problem between layers formed by FCVA (e.g. to-C) and sputtering layers by avoiding an abrupt transition between the respective materials.

It is possible to make use of this simultaneous co-deposition method in order to provide a multi-layer coating comprising a layer deposited via a CVA method and another layer deposited via a sputtering method, where the layer deposited using the co-deposition methods promotes adhesion between the two aforementioned layers. This transition layer is formed according to Method A above.

Accordingly, the invention also provides a method (“Method B”) of depositing a coating comprising a first material and a second material on a substrate, the method comprising:
i) depositing the first material via a CVA process to form a lower layer;
ii) simultaneously depositing the first material via the CVA process and the second material via a sputtering process to form a transition layer; and
iii) depositing the second material via a sputtering process to form an upper layer.

Alternatively, the lower layer may be deposited by sputtering and the upper layer by CVA, with the transition layer being formed by simultaneous CVA and sputtering processes. Again, the transition layer (i.e. the layer deposited using a co-deposition method) promotes adhesion between the lower and upper layers. The transition layer is again formed according to Method A above.

Therefore, the invention also provides a method (“Method C”) of depositing a coating comprising a first material and a second material on a substrate, the method comprising:
i) depositing the second material via a sputtering process to form a lower layer;
ii) simultaneously depositing the first material via a CVA process and the second material via a sputtering process to form a second layer; and
iii) depositing the first material via the CVA process to form a third layer.

The terms “lower layer” and “upper layer” are terms relative to the other layers described. There may be additional layers beneath the lower layer and there may also be additional layers above the upper layer. The lower layer is more proximal to the substrate than the transition layer and upper layer and is hence deposited before the transition and upper layers are deposited. The upper layer is more distal from the substrate than the transition layer and lower layer and is hence deposited after both the transition and lower layers have been deposited.

The first material is preferably a carbon-containing material, for example an amorphous carbon (such term including both DLC and to-C). The first material preferably comprises or consists of to-C. There may be several such first layers (e.g. all comprising or consisting of to-C), with Young's modulus and/or hardness remaining the same or increasing from layer to layer, suitably peaking or culminating with the properties of an uppermost ta-C layer, usually the one exposed on the outside of the coated substrate.

The total thickness of the one or more layers deposited by CVA only (i.e. the lower layer in Method B and the upper layer in Method C) is typically from 0.05 μm to 2 μm, preferably from 0.1 μm to 1.7 μm, more preferably from 0.2 μm to 1.5 μm and even more preferably from 0.5 μm to 1.0 μm.

An aim of the invention is to provide hard coatings which are stable and able to maintain their hardness and wear resistance at high temperatures. Coated substrates of the invention preferably have a coating with a hardness of at least 800 HV, preferably 1000 HV or more. Coatings with a wide range of measured hardness values within these ranges have been made (see examples below), including coatings with hardness of approximately 1000 HV.

The second material may be the same as or different to the first material, but is typically different to the first material. The second material can be any material that can be deposited by sputtering. The second material may be selected from Ti, Cr, Si, Zr, Al, C, W and alloys and compounds thereof. The second material may be selected depending on the desired property of the coating. For example, when the second material is the uppermost layer of the coating, the second material may be selected based on its colour to impart a particular aesthetic property to the coating. Examples of preferred second materials include CrSiC, CrWC, CrAlSICN and CrN; note that this nomenclature indicates components of the material but not their precise ratios.

The thickness of the layer deposited by sputtering (i.e. the upper layer in Method B and the lower layer in Method C) is typically from 0.05 μm to 1.0 μm, for example from 0.1 μm to 0.5 μm, preferably from 0.2 μm to 0.4 μm.

Layers deposited via sputtering typically have lower hardness and Young's modulus values compared to layers deposited via a CVA process. This is particularly the case when the material deposited via the CVA process is to-C. The second layer (i.e. the layer deposited via simultaneous sputtering and CVA processes) typically therefore has a Young's modulus and/or hardness value which is intermediate between those of the first and third layers. This has been found to promote adhesion.

As mentioned above, magnetron sputtering usually occurs at a pressure of about 2 mTorr to 10 mTorr (0.27 Pa to 1.33 Pa), whereas for CVA the normal working pressure is typically less than 2.0E-5 Torr (2.7 mPa). In the co-deposition step of the invention, pressures of between 0.5 mTorr and 1.0 mTorr (0.067 Pa and 0.13 Pa) have successfully been used to date.

Accordingly, for Methods B and C of the invention:
deposition of the first/second materials via an CVA process may occur at pressures of 0.1 Pa or less, typically 10 mPa or less, for example 3 mPa or less; and/or
simultaneously deposition via the CVA process and sputtering process may take place at a pressure of from 0.05 Pa to 0.15 Pa, for example from 0.06 Pa to 0.13 Pa; and/or
deposition of the first/second materials via a sputtering process may occur at pressures of 0.2 Pa or greater, for example from 0.2 to 1.4 Pa.

Accordingly, in Method B, the pressure at which deposition takes place increases from step i) to step ii) to step iii) and in Method C, the pressure at which deposition takes place decreases from step i) to step ii) to step iii).

The thickness of the transition layer is typically from 0.05 μm to 1 μm, for example from 0.05 μm to 0.5 μm, preferably from 0.1 μm to 0.3 μm.

Choice of suitable substrate to be coated is not particularly restricted in any way. Specific substrates include plastics materials, ceramic materials, rubber, metals and graphite. In one preferred method, the substrate is made from (comprises or consists of) a metal (e.g. steel). In another preferred method, the substrate is made from graphite.

The coating may further optionally comprise a seed layer between the substrate and lower layer (i.e. the layer deposited via CVA). The seed layer is included to promote adhesion of the lower layer to the underlying substrate. The nature of the seed layer will therefore depend on the nature of the substrate and the material in the lower layer (i.e. the first material in Method B and the second material in Method C). Examples of suitable seed layers include materials comprising Cr, W, Ti, NiCr, Si or mixtures thereof. When the substrate is a steel substrate, examples of preferred materials for the seed layer are Cr and NiCr.

The thickness of the seed layer is typically from 0.05 μm to 1 μm, for example from 0.05 μm to 0.5 μm, preferably from 0.1 μm to 0.5 μm.

Accordingly, the total thickness of the coatings is typically from 0.5 μm to 5 μm, preferably from 0.5 μm to 3 μm, most preferably from 1 μm to 3 μm.

The invention also provides a substrate coated with a coating comprising:
i) a layer deposited via a sputtering process;
ii) a transition layer between (i) and (iii) deposited by a process comprising simultaneous CVA deposition and a sputtering process; and
iii) a layer deposited by CVA deposition.

Optional and preferred embodiments for all aspects of the coated substrate are as described elsewhere herein in relation to methods of the invention. For example, the layer (iii) suitably comprises or consists of to-C.

Specific types of coated substrates according to the invention, comprise, in order:
(a) a seed layer comprising NiCr and having a thickness of from 0.1 μm to 0.2 μm;
(b) a first layer comprising to-C deposited by CVA and having a thickness of from 0.4 μm to 0.6 μm;
(c) a second layer comprising to-C deposited by CVA and metal or metal alloy or metal compound deposited by sputtering, the second layer having a thickness of from 0.1 μm to 0.2 μm; and
(d) a third layer comprising the metal or metal alloy or metal compound deposited by sputtering and having a thickness of 0.1 μm to 0.2 μm.

Other specific coated substrate types according to the invention, comprise, in order:
(a) a steel substrate;
(b) a seed layer comprising Cr deposited by sputtering and having a thickness of from 0.1 μm to 0.2 μm;
(c) a layer comprising both to-C deposited by CVA and Cr deposited by sputtering;
(d) a layer comprising to-C deposited by CVA and having a thickness of from 0.4 μm to 0.6 μm;
(e) a layer comprising both to-C deposited by CVA and metal or metal alloy or metal compound deposited by sputtering and having a thickness of from 0.1 μm to 0.2 μm; and
(f) a layer comprising the metal or metal alloy or metal compound deposited by sputtering and having a thickness of 0.2 μm to 0.4 μm.

In the above, the coating comprises two co-deposited transition layers of the invention. The first transition layer (layer c) promotes adhesion between the seed layer and the ta-C layer. The second transition layer (layer e) promotes adhesion between the ta-C layer and the top, (coloured) sputtered layer.

Further specific coated substrates according to the invention comprise, in order:
(a) a graphite substrate;
(b) a sputtered seed layer of SiC and having a thickness of from 0.1 μm to 0.2 μm;
(c) a sputtered layer of Si₃N₄ having a thickness of from 0.1 μm to 1.0 μm;
(d) a further sputtered layer of SiC having a thickness of from 0.1 μm to 0.2 μm
(e) a layer comprising both ta-C deposited by CVA and SiC deposited by sputtering and having a thickness of 0.1 μm to 0.5 μm; and
(f) a layer comprising ta-C deposited by CVA and having a thickness of from 0.4 μm to 0.6 μm.

The invention also provides a coating apparatus comprising:
a substrate station, for location of a substrate to be coated;
a CVA station, for depositing material via CVA onto the substrate;
a sputtering station, for depositing material via a sputtering process onto the substrate; and
a control unit that is capable of operating the CVA and sputtering stations simultaneously.

The substrate station, CVA station and sputtering station are typically all located in a chamber of the apparatus. The chamber is preferably also provided with a pump for controlling the pressure within the chamber.

Typically, the CVA station is an FCVA station, for depositing material via FCVA onto the substrate. The sputtering station is suitably a magnetron sputtering station.

The optional and preferred features of the processes of the present invention apply equally to the coating apparatus of the present invention, in particular (but not limited to) the features of the CVA and sputtering processes described herein.

Conventional sputtering and CVA processes are known and used for a wide range of substrates and the methods of the invention are similarly suitable for coating a wide range of substrates.

Coatings of the invention are multilayered and the respective layers may be deposited using a range of known and conventional deposition techniques, including CVD, PVD, HiPIMS, magnetron sputtering and multi-arc ion plating. The CVA process is typically a filtered cathodic vacuum arc (FCVA) process, e.g. as described below. Apparatus and methods for FCVA coatings are known and can be used as part of the methods of the invention. The FCVA coating apparatus typically comprises a vacuum chamber, an anode, a cathode assembly for generating plasma from a target and a power supply for biasing the substrate to a given voltage. The nature of the FCVA is conventional and not a part of the invention.

Hardness is suitably measured using the Vickers hardness test (developed in 1921 by Robert L. Smith and George E. Sandland at Vickers Ltd; see also ASTM E384-17 for standard test), which can be used for all metals and has one of the widest scales among hardness tests. The unit of hardness given by the test is known as the Vickers Pyramid Number (HV) and can be converted into units of pascals (GPa). The hardness number is determined by the load over the surface area of the indentation used in the testing. As examples. Martensite a hard form of steel has HV of around 1000 and diamond can have a HV of around 10,000 HV (around 98 GPa). Hardness of diamond can vary according to precise crystal structure and orientation but hardness of from about 90 to in excess of 100 GPa is common.

The invention advantageously provides coatings formed from sputtered materials with increased hardness and wear resistance.

### BRIEF DESCRIPTION OF THE DRAWINGS

The invention is now illustrated with reference to the accompanying drawings in which:

FIG. 1 is a schematic diagram showing the structure of the coating of the invention described in Example 1 (not to scale).

### EXAMPLES

### Example 1

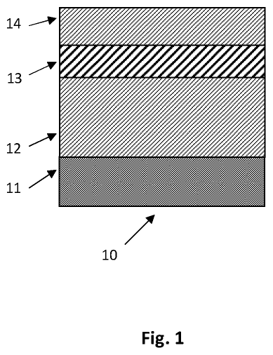

A first example of the coating of the invention (see FIG. 1, 10) was prepared as described below:

| Layer | Thickness |
|---|---|
| SPT* (14) | 0.3 μm |
| ta-C + SPT* (13) | 0.4 μm |
| ta-C (12) | 0.8 μm |
| Substrate (11) - SUS304 Steel | |
| Total Thickness | ~1.5 μm |
| (determined by CAR2) | |

SPT*—a range of materials deposited by sputtering was used to form a range of coatings with different coloured uppermost layers:

| SPT* material | Colour |
|---|---|
| CrSiC | Charcoal |
| CrWC | Black |
| CrAlSiCN | Blue |
| CrN | Silver |

i. Start FCVA ta-C deposition first, gradually increasing input Ar pressure to a pressure of between 0.5 to 1.0 mTorr ;

ii. Keep the pressure constant steady and begin magnetron sputtering;

iii. After a certain time (e.g. a time period sufficient to generate a co-deposited layer with a thickness of about 400 nm), stop FCVA coating and continue sputtering to form the top layer

### Example 2

The hardness of the coatings prepared in Example 1 were determined by using a nanoindenter (CSM NHT2). These values were compared with the hardness of coatings produced using sputtering only (i.e. sputtering the SPT material directly onto the substrate).

| | | CrSiC | CrWC | CrAlSiCN | CrN |
|---|---|---|---|---|---|
| Hardness (HV) | SPT only | 680 | 500 | 660 | 1200 |
| | (Comparative | | | | |
| | Examples) | | | | |
| | SPT & ta-C | 1250 | 950 | 1100 | 1530 |
| | (Example 1) | | | | |

### Example 3—Cross Hatch

To check the level of adhesion of the coating to the substrate, a cross hatch test was conducted based on the ASTM D-3359 Test Method B. A lattice pattern with grid dimensions of 1.0 mm by 1.0 mm was cut into the surface of the coating. Pressure sensitive 51596 was then applied to the cut coating and removed.

In both the coatings of Example 1 and the corresponding Comparative Coatings (containing only a sputtered layer of the SPT material), the peel-off area was less than 5%.

### Example 4—Steel Wool Abrasion Test

As an indication of the wear-resistance of the coatings of Example 1, a Taber abrasion test was conducted on the coatings, with the following conditions:
Instrument: Taber Linear Abraser Test
Abradant: Steel Wool
Test Load: 500g weight
Cycle Speed: 60 cycles/min
Stroke Length: 5 mm

After 400 cycles, there were no noticeable scratches on the surface of the coatings of Example 1. When corresponding substrates coated with only the SPT materials (i.e. without the ta-C layer or the transition layer containing ta-C and SPT) were subject to the same conditions, visible scratches were observed.

### Example 5—Blue Jean Abrasion Test

As an indication of the wear-resistance of the coatings of Example 1, a Taber abrasion test was conducted on the coatings, with the following conditions:
Instrument: Taber Linear Abraser Test
Abradant: Levis blue jean material
Test Load: 500 g weight
Cycle Speed: 60 cycles/min
Stroke Length: 5 mm

After 1000 cycles, there were no noticeable scratches on the surface of the coatings of Example 1. When corresponding substrates coated with only the SPT material (i.e. without the ta-C layer or the transition layer containing ta-C and SPT) were subject to the same conditions, visible scratches were observed.

### Example 6—Salt Spray Test

As an indication of the corrosion-resistance of the coatings of Example 1, a salt spray test was conducted on the coatings. The salt spray test was based on ASTM B117: Standard

Practice for Operating Salt Spray (Fog) and comprised spraying a 5% salt water solution onto the coated substrates at a temperature of 35° C.

After 72 hours, there were no visible signs of rust or degradation of the coatings of Example 1. When corresponding substrates coated with only the SPT material (i.e. without the ta-C layer or the transition layer containing ta-C and SPT) were subject to the same conditions for 72 hours, corrosion was observed.

As can be seen in the Example above, coatings of the invention can have increased hardness, wear resistance and corrosion resistance compared to the comparative coatings.

1. A method of depositing a coating on a substrate, the method comprising simultaneously depositing a first material via a CVA process and a second material via a sputtering process, characterised in that the first material comprises to-C.

2. A method according to claim 1 of depositing a coating comprising a first material and a second material on a substrate, the method comprising:
i) depositing the first material via a CVA process to form a lower layer;
ii) simultaneously depositing the first material via the CVA process and the second material via a sputtering process to form a transition layer; and
iii) depositing the second material via a sputtering process to form an upper layer.

3. A method according to claim 1 of depositing a coating comprising a first material and a second material on a substrate, the method comprising:
i) depositing the second material via a sputtering process to form a lower layer;
ii) simultaneously depositing the first material via the CVA process and the second material via a sputtering process to form a transition layer; and
iii) depositing the first material via a CVA process to form an upper layer.

4. A method according to claim 1, wherein the CVA process is FCVA.

5. A method according to claim 1, wherein the first material consists of to-C.

6. A method according to claim 1, wherein the second material is selected from Ti, Cr, Si, Zr, C, W and alloys and compounds thereof.

7. A method according to claim 1, further comprising depositing a seed layer onto the substrate prior to coating it with the first and second materials, and optionally wherein the seed layer has a thickness of from 0.1 μm to 0.5 μm.

8. A method according to claim 1, wherein the substrate is a metallic substrate.

9. A method according to claim 8 wherein the substrate is a steel substrate.

10. A method according to claim 2 wherein the first layer has a thickness of 0.2 μm to 1.5 μm, and/or the second layer has a thickness of 0.1 μm to 0.3 μm.

11. A method according to claim 1 wherein the coating has a thickness of from 0.5 μm to 5 μm.

12. A method according to claim 11 wherein the coating has a thickness of from 1.0 μm to 3.0 μm.

13. A method according to claim 1 wherein the coating takes place in a chamber at a pressure of 0.5 Pa or less.

14. A coated substrate obtainable from a method according to claim 1.

15. A substrate coated with a coating, wherein the coating comprises:
i) a layer deposited via a sputtering process;
ii) a transition layer between (i) and (iii) deposited by a process comprising simultaneous CVA deposition and a sputtering process; and
iii) a ta-C layer deposited by CVA deposition.

16. A coating apparatus comprising:
a substrate station, for location of a substrate to be coated;
a CVA station, for depositing ta-C via CVA onto the substrate;
a sputtering station, for depositing material via a sputtering process onto the substrate; and
a control unit that is capable of operating the CVA and sputtering stations simultaneously.
